(19) United States
(12) Patent Application Publication
(10) Pub. No.: US 2008/0037310 A1
(43) Pub. Date: Feb. 14, 2008

(54) Semiconductor memory device and connection method thereof

(75) Inventors: Akihiro Kasahara, Sambu-gun (JP); Hiroshi Suu, Chigasaki-shi (JP); Akira Miura, Sagamihara-shi (JP); Shinji Saito, Yokohama-shi (JP)

Correspondence Address: Charles N.J. Ruggiero, Esq.;Ohlandt, Greeley, Ruggiero & Perle, L.L.P., One Landmark Square, 10th Floor, Stamford, CT, 06901-2682, US

(73) Assignee: KABUSHIKI KAISHA TOSHIBA

(21) Appl. No.: 11/821,830

(22) Filed: Jun. 26, 2007

(30) Foreign Application Priority Data
Jun. 30, 2006 (JP) 2006-182273

(51) Int. Cl. G11C 5/06

(52) U.S. Cl. 365/63

(57) ABSTRACT

A semiconductor memory device comprising a substrate, a memory electrically connected to the substrate, a first and a second transmission/reception units transmitting a signal supplied by the memory and receiving a signal to be supplied to the memory, both arranged on a surface of the substrate, a branch circuit which is electrically connected to the first and the second transmission/reception units, and electrically discriminates the second transmission/reception unit from the memory, and a conversion circuit which converts the signal between the branch circuit and the memory into a signal in a predetermined format.

### CROSS-REFERENCE TO RELATED APPLICATIONS

This application is based upon and claims the benefit of priority from prior Japanese Patent Application No. 2006-182273, filed Jun. 30, 2006, the entire contents of which are incorporated herein by reference.

### BACKGROUND OF THE INVENTION

1. Field of the Invention

The present invention relates to a semiconductor memory device and connection method thereof and, more particularly, to a USB memory.

2. Description of the Related Art

In recent years, along with an increase in the capacity of a nonvolatile memory such as a NAND flash memory, a demand for a portable semiconductor memory device such as a USB (Universal Serial Bus) memory or memory card is growing.

For example, the USB memory is connected to the USB terminal of a host apparatus such as a PC (Personal Computer), and functions as an external memory (e.g., see JP-A 2006-94441 (KOKAI)).

However, there are many host apparatuses such as a home component stereo and car stereo each having only one USB terminal. Hence, in order to increase the capacity and number of functions of a memory to be connected to such host apparatus, the number of terminals of the host apparatus need be increased, or a hub need be prepared to connect memories. This is disadvantageous in saving a space.

### BRIEF SUMMARY OF THE INVENTION

According to an aspect of the present invention, there is provided a semiconductor memory device comprising a substrate, a memory electrically connected to the substrate, a first and a second transmission/reception units transmitting a signal supplied by the memory and receiving a signal to be supplied to the memory, both arranged on a surface of the substrate, a branch circuit which is electrically connected to the first and the second transmission/reception units, and electrically discriminates the second transmission/reception unit from the memory, and a conversion circuit which converts the signal between the branch circuit and the memory into a signal in a predetermined format.

According to another aspect of the present invention, there is provided a connection method of a semiconductor memory which includes a substrate, a memory mounted on the substrate, a first and a second transmission/reception units transmitting a signal supplied by the memory and receiving a signal to be supplied to the memory, both arranged on a surface of the substrate, a branch circuit which is electrically connected to the first and the second transmission/reception units, and electrically discriminates the second transmission/reception unit from the memory, and a conversion circuit which converts the signal between the branch circuit and the memory into a signal in a predetermined format, the method comprising, electrically connecting the first transmission/reception unit and the second transmission/reception unit via the branch circuit, and connecting the plurality of semiconductor memory devices in a staggered pattern.

### BRIEF DESCRIPTION OF THE SEVERAL VIEWS OF THE DRAWING

FIG. 1A is a plan view showing a semiconductor memory device when viewed from a male USB terminal according to the first embodiment;

FIG. 1B is a plan view showing the semiconductor memory device when viewed from above according to the first embodiment;

FIG. 1C is a plan view showing the semiconductor memory device when viewed from a female USB terminal according to the first embodiment;

FIG. 2 is a plan view showing a substrate extracted from the semiconductor memory device according to the first embodiment;

FIG. 3 is a block diagram showing the circuit arrangement of the semiconductor memory device according to the first embodiment;

FIG. 4 is a plan view for explaining a connection operation of two USB memories according to the first embodiment;

FIG. 5 is a plan view for explaining the connection operation of the two USB memories according to the first embodiment;

FIG. 6 is a block diagram showing the circuit arrangement when connecting the two USB memories according to the first embodiment;

FIG. 7 is a plan view for explaining a connection operation of a plurality of USB memories according to the first embodiment;

FIG. 8 is a plan view for explaining the connection operation of the plurality of USB memories according to the first embodiment;

FIG. 9 is a block diagram showing the circuit arrangement when connecting the plurality of USB memories according to the first embodiment;

FIG. 10 is a plan view for explaining a connection operation of the plurality of memories each having male and female USB terminals arranged on different surfaces of the substrate;

FIG. 11 is a plan view showing a semiconductor memory device according to the second embodiment;

FIG. 12 is a block diagram showing the circuit arrangement of the semiconductor memory device according to the second embodiment;

FIG. 13 is a plan view for explaining a connection operation of two USB memories according to the second embodiment;

FIG. 14 is a block diagram showing the circuit arrangement when connecting the two USB memories according to the second embodiment;

FIG. 15 is a view showing a state wherein the USB memories are connected to a home component stereo according to the second embodiment;

FIG. 16 is a view showing a state wherein the USB memories are connected to a car stereo according to the second embodiment;

FIG. 17 is a plan view showing a USB memory according to a modification;

FIG. 18 is a plan view showing a USB memory according to a modification;

FIG. 19 is a plan view showing a USB memory according to a modification;

FIG. 20 is a plan view showing a USB memory according to a modification;

FIG. 21 is a plan view showing a USB memory according to a modification;

FIG. 22 is a plan view showing a USB memory according to a modification;

FIG. 23 is a plan view showing a semiconductor memory device according to the third embodiment;

FIG. 24 is a plan view showing a substrate extracted from the semiconductor memory device according to the third embodiment;

FIG. 25 is a block diagram showing the circuit arrangement of the semiconductor memory device according to the third embodiment; and

FIG. 26 is a block diagram showing the circuit arrangement when connecting the plurality of semiconductor memory devices according to the third embodiment.

### DETAILED DESCRIPTION OF THE INVENTION

Embodiments of the present invention will be described below with reference to the accompanying drawing. In this description, common reference numerals denote common parts throughout the drawings.

### First Embodiment

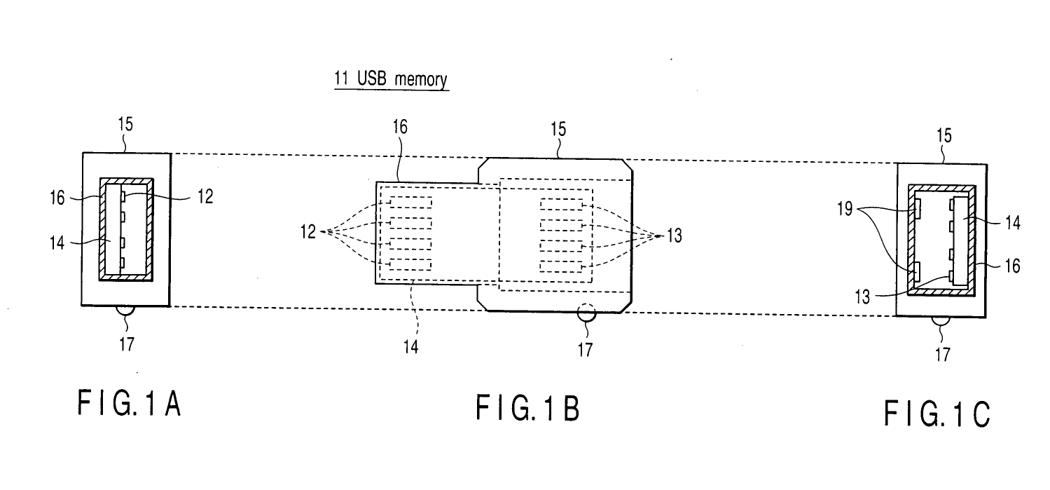

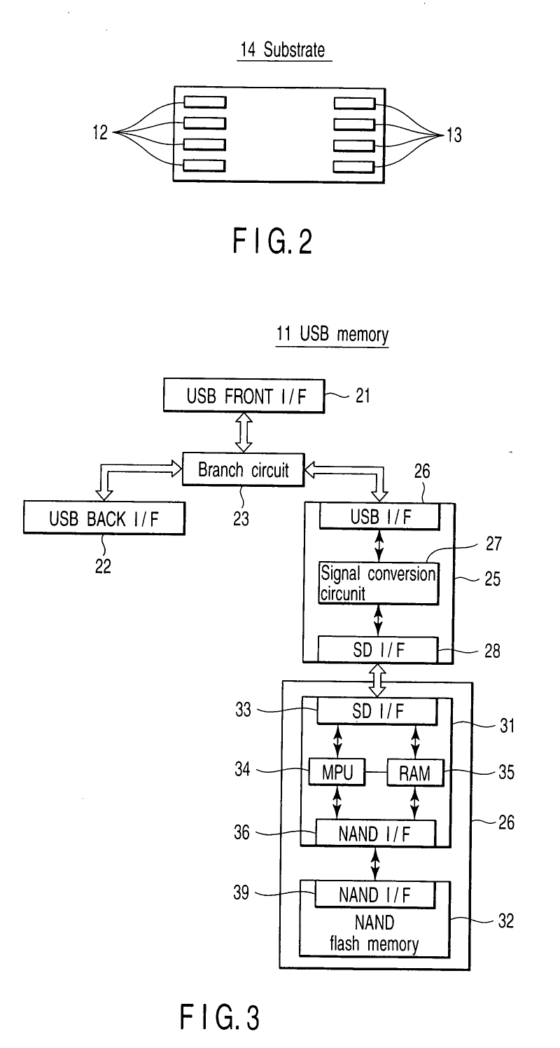

An outline of a semiconductor memory device according to the first embodiment of the present invention will be described first with reference to FIGS. 1A to 1C and FIG. 2. FIG. 1A is a plan view showing the semiconductor memory device when viewed from a male USB terminal according to the first embodiment. FIG. 1B is a plan view showing the semiconductor memory device when viewed from above according to the first embodiment. FIG. 1C is a plan view showing the semiconductor memory device when viewed from a female USB terminal according to the first embodiment. FIG. 2 is a plan view showing the substrate of the semiconductor memory device according to this embodiment. This embodiment will be explained below by taking a universal serial bus memory (to be referred to as a USB memory hereinafter) as an example. As shown in FIGS. 1A to 1C and FIG. 2, a USB memory 11 includes male USB terminals (a first transmission/reception unit) 12, female USB terminals (a second transmission/reception unit) 13, a substrate 14, a frame 16, springs 19, a housing 15, and a side indicator 17.

The plurality of (in this embodiment, four) male USB terminals 12 are arranged at one end of the substrate 14.

On the substrate 14, the plurality of (in this embodiment, four) female USB terminals 13 are arranged at the other end of the same surface on which the male USB terminals 12 are arranged.

The substrate 14 on which the male USB terminals 12, female USB terminals 13, and the like are arranged is, e.g., a printed circuit board. A memory 26 (to be described later) and the like are soldered on the substrate 14.

The frame 16 covers the male USB terminals 12 to support the USB memory 11 and increase its mechanical strength when the male USB terminals 12 are inserted into the USB terminal of a host apparatus or when the male USB terminals of another memory (to be described later) are inserted into the female USB terminals 13. The frame 16 is made of, e.g., stainless steel.

When the male USB terminals of another memory are inserted into the female USB terminals 13, the springs 19 press both substrates to connect these female and male USB terminals by pressure.

The housing 15 covers the male USB terminals 12, female USB terminals 13, substrate 14, and frame 16.

When the USB memory 11 is connected to another USB memory (to be described later), the side indicator 17 arranged on the side surface of the housing 15 indicates that the USB memory 11 is in operation. More specifically, the side indicator 17 is mounted on the surface of the housing 15 in correspondence with the side surface of the substrate 14. For example, the side indicator 17 comprises a light-emitting diode or the like to continuously emit light while the memory 11 is in operation. In this embodiment, the side indicator 17 is mounted on one side surface of the housing 15. However, side indicators 17 may be arranged on both side surfaces of the housing 15.

The arrangement of the semiconductor memory device according to this embodiment will be described in more detail with reference to FIG. 3. FIG. 3 is a block diagram for explaining the semiconductor memory device according to this embodiment.

As shown in FIG. 3, the USB memory 11 includes a USB front interface (to be referred to as a USB front I/F hereinafter) 21, a USB back interface (to be referred to as a USB back I/F hereinafter) 22, a branch circuit 23, a conversion circuit 25, and the memory (in this embodiment, an integrated SD™ memory card) 26.

The USB front I/F 21 is electrically connected to the male USB terminal 12. The USB memory 11 transmits/receives, via the USB front I/F 21, data and the like to/from the host apparatus or the like which is connected to the male USB terminal 12.

The USB back I/F 22 is electrically connected to the female USB terminal 13. The USB memory 11 transmits/receives, via the USB back I/F 22, data and the like to/from another USB memory or the like which is connected to the female USB terminal 13.

The branch circuit 23 is soldered on the substrate 14 (not shown). The branch circuit 23 electrically discriminates another USB memory or the like connected to the USB back I/F 22 from the memory 26 of the memory 11, and transmits/receives data and the like.

The conversion circuit 25 is soldered on the substrate 14 (not shown). The conversion circuit 25 converts, into a signal in a predetermined format, a signal such as data to be transmitted/received between the branch circuit 23 and the memory 26. In this embodiment, the conversion circuit 25 converts a signal defined in a hub format based on the USB memory into a signal defined based on the SD™ memory card, and, in return, converts a signal defined based on the SD™ memory card into a signal defined in the hub format based on the USB memory. The conversion circuit 25 includes a USB I/F 26, signal conversion circuit 27, and SD I/F 28.

The USB I/F 26 is formed based on the USB memory to transmit/receive data and the like between the signal conversion circuit 27 and the branch circuit 23.

The signal conversion circuit 27 converts the signal defined based on the USB memory into a signal defined based on the SD™ memory card, and, in return, converts a signal defined based on the SD™ memory card into a signal defined based on the USB memory.

The SD I/F 28 is formed based on the SD™ memory card to transmit/receive data and the like between the signal conversion circuit 27 and the memory 26.

In this embodiment, the memory 26 is an integrated SD™ memory card to store music data and the like transmitted from the conversion circuit 25. The memory 26 includes a controller 31 and a NAND flash memory 32.

The controller 31 manages the physical state (e.g., which logical sector address data is saved in which physical block address, or which block is erased) in the NAND flash memory 32. The controller 31 controls the NAND flash memory 32 to input/output data, manage the data, add an error correction code (ECC) when writing the data, and analyze and process the ECC when reading out the data. The controller 31 includes an SD I/F 33, MPU (Micro Processing Unit) 34, RAM (Random Access Memory) 35, and NAND I/F 36.

The SD I/F 33 is formed based on the SD™ memory card to transmit/receive data and the like between the conversion circuit 25 and the controller 31.

The MPU 34 controls the operations of the overall memory 26. The MPU 34 also receives a write command, read command, and erase command from the host apparatus (not shown), executes a predetermined process for the NAND flash memory 32, and controls a data transfer process via the RAM 35.

For example, when writing data and the like from the host apparatus (not shown) into the NAND flash memory 32, the RAM 35 temporarily stores a predetermined amount of data (e.g., data for one page).

The NAND flash memory 32 stores music data, image data, and the like. The NAND flash memory 32 may be a binary NAND flash memory which can record 1-bit data in each memory cell, or a multilevel NAND flash memory which can record several-bit data in each memory cell. Also, the NAND flash memory 32 may comprise more than one binary or multilevel NAND flash memories.

The nonvolatile memory cells which store the data of the NAND flash memory 32 are arrayed at the intersections between bit lines and word lines in a matrix (not shown). Each memory cell has a stacked structure of a tunnel insulating film formed on the semiconductor substrate, a floating electrode formed on the tunnel insulating film, an inter-gate insulating film formed on the floating electrode, and a control electrode formed on the inter-gate insulating film. The memory cells adjacent along the bit line direction share a source/drain region serving as a current path. For example, 32 current paths are connected in series.

The NAND I/F 36 is formed based on the NAND flash memory 32 to transmit/receive data and the like between the controller 31 and the NAND flash memory 32.

<Connection Operation of USB Memories (Connection Operation of Two USB Memories)>

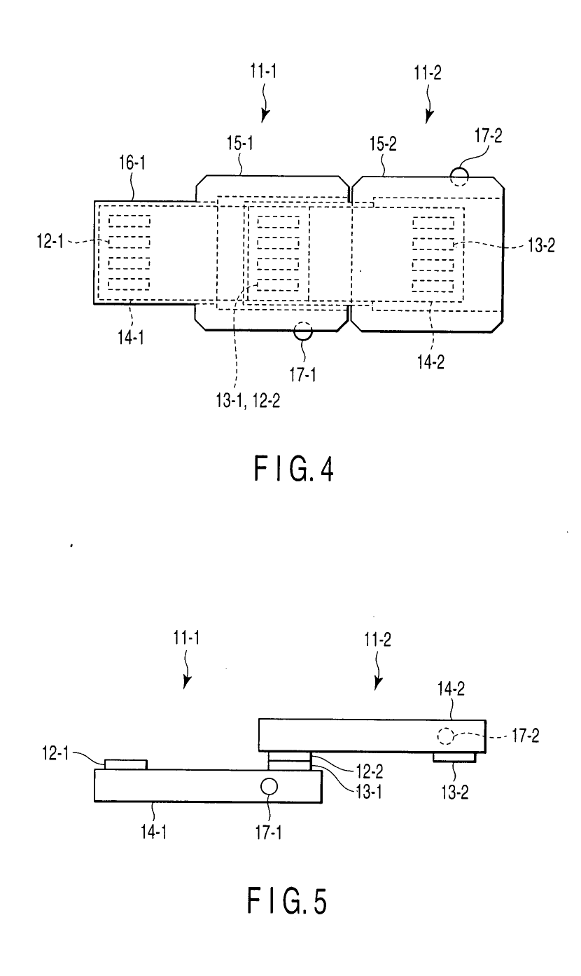

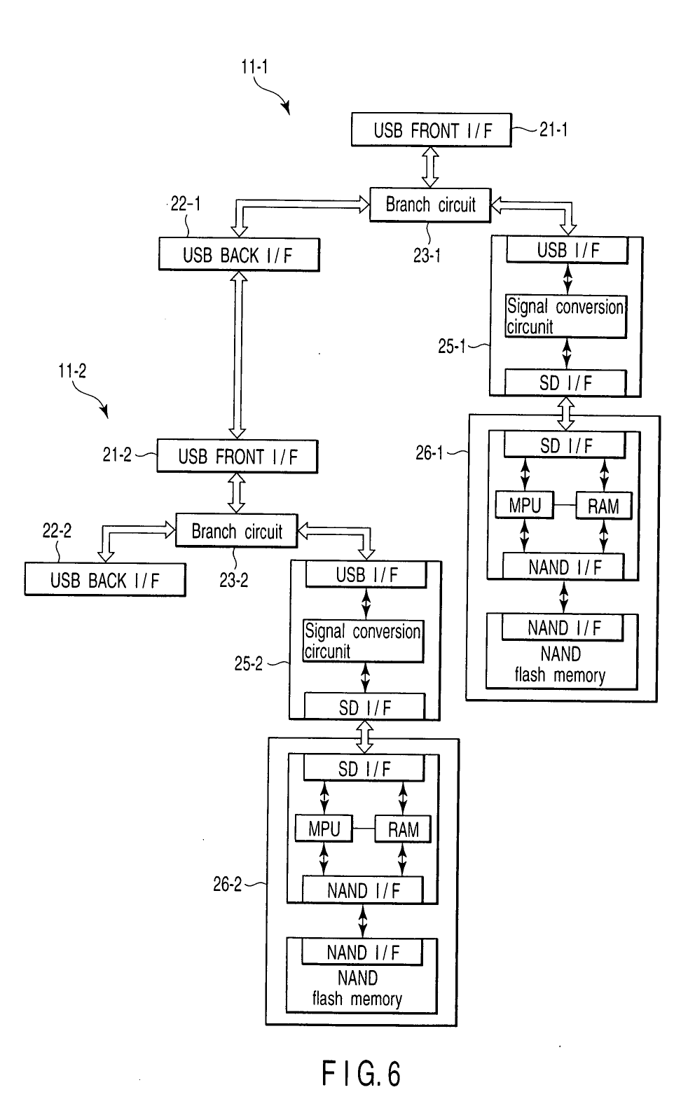

The connection operation of the USB memories according to this embodiment will be described below with reference to FIGS. 4 to 6. FIGS. 4 and 5 are views for explaining the connection operation of the USB memories according to this embodiment. FIG. 6 is a block diagram when connecting the USB memories according to this embodiment. In this description, assume that two USB memories 11-1 and 11-2 each having the same arrangement as that of the USB memory 11 are connected.

As shown in FIGS. 4 to 6, a male USB terminal 12-2 of the USB memory 11-2 is inserted into a female USB terminal 13-1 of the USB memory 11-1 to connect the USB memories 11-1 and 11-2 to each other.

In this case, the spring 19 presses both substrates 14-1 and 14-2 by its elasticity, and the female and male USB terminals 13-1 and 12-2 are connected by pressure to be electrically connected.

With this operation, the USB memories 11-1 and 11-2 are connected via a USB back I/F 22-1 and a USB front I/F 21-2 to drive both memories 26-1 and 26-2 using branch circuits 23-1 and 23-2. Additionally, in this case, side indicators 17-1 and 17-2 continuously emit light to indicate that the USB memories 11-1 and 11-2 are in operation.

<Connection Operation of USB Memories (Connection Operation of Three or more USB Memories)>

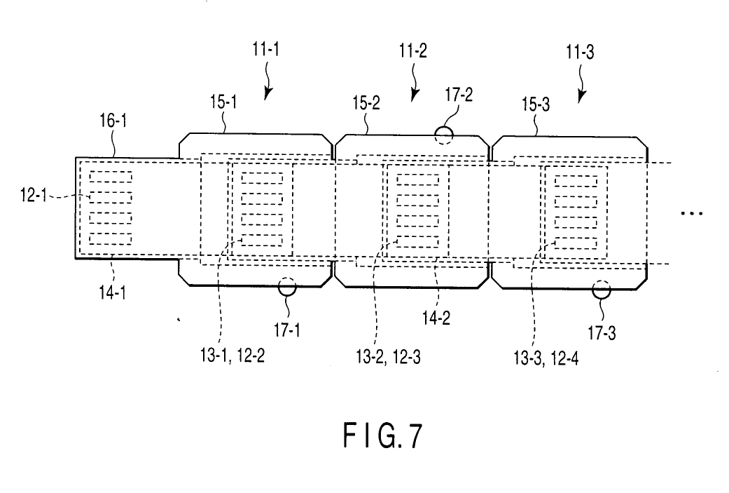

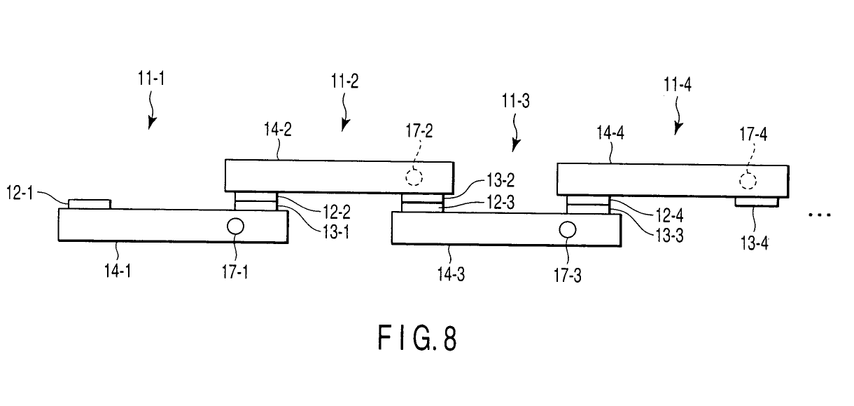

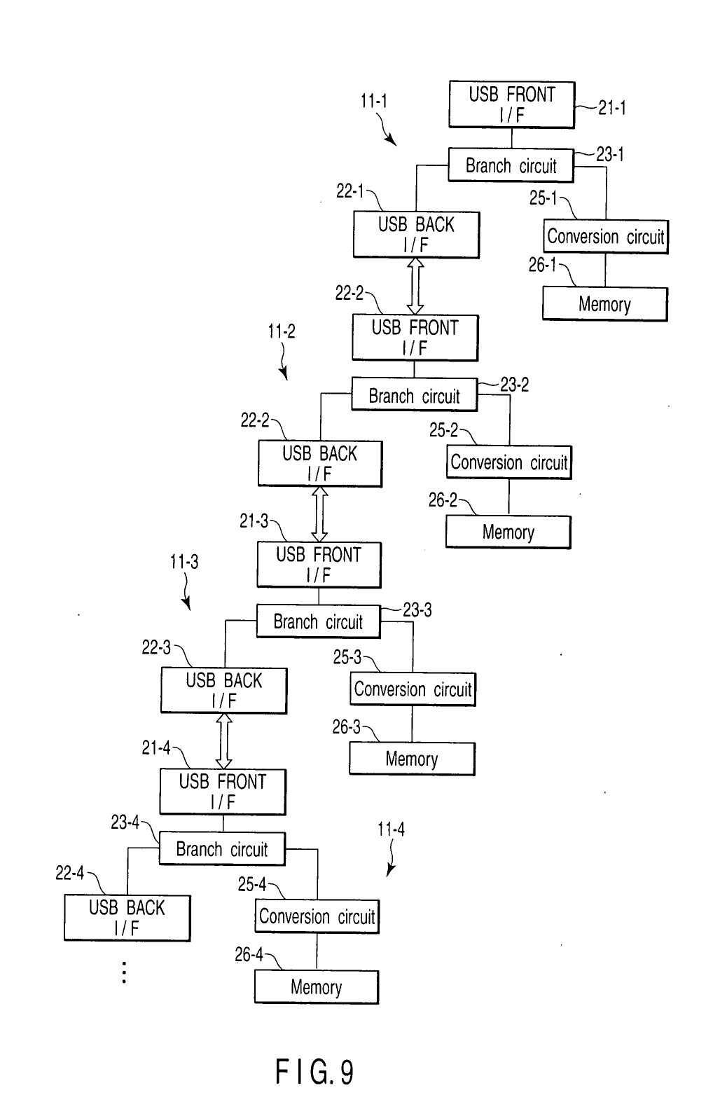

The connection operation of the plurality of USB memories according to this embodiment will be described below with reference to FIGS. 7 to 10. FIGS. 7 and 8 are views for explaining the connection operation of the USB memories according to this embodiment. FIG. 9 is a block diagram when connecting the USB memories according to this embodiment. In this description, assume that three or more USB memories 11-1 to 11-4, . . . each having the same arrangement as that of the USB memory 11 are connected.

As shown in FIGS. 7 to 10, a male USB terminal 12-3 of the USB memory 11-3 is inserted into a female USB terminal 13-2 of the USB memory 11-2 to connect the USB memories 11-2 and 11-3 to each other. After that, the same connection operation is repeated for the remaining USB memories 11-3, 11-4, . . . .

All the USB memories 11-1 to 11-4, . . . are connected via the USB back I/Fs and the USB front I/Fs to drive all memories 26-1 to 26-4, . . . using branch circuits 23-1 to 23-4, . . . . Additionally, in this case, side indicators 17-1 to 17-4, . . . continuously emit light to indicate that the USB memories 11-1 to 11-4, . . . are in operation.

With this arrangement, the USB memories 11-1 to 11-4, . . . according to this embodiment can be connected in series in a staggered pattern (FIGS. 8 and 9).

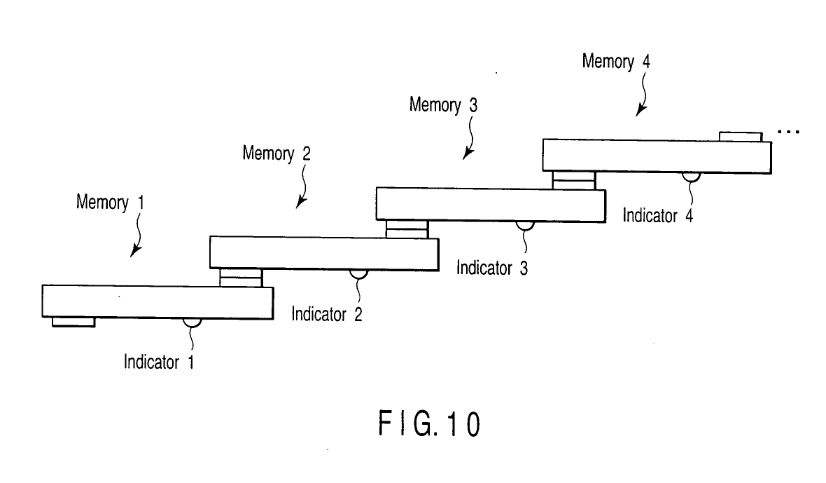

On the other hand, when connecting a plurality of USB memories each having female USB terminals arranged on the surface of the substrate opposite to the surface on which male USB terminals are arranged, the USB memories are connected in a step-like shape (FIG. 10). Furthermore, when connecting a plurality of USB memories each having an indicator arranged on the lower surface of the housing, it may not be possible to confirm the operations of the USB memories (FIG. 10). In this case, a similar problem may arise (not shown) even when the indicators are arranged on the upper surfaces of the housings.

The semiconductor memory device and connection method thereof according to this embodiment have the following effects (1) and (2).

(1) Advantageous in Saving Space

As described above, the USB memory 11 according to this embodiment includes the male USB terminal 12 and female USB terminal 13 arranged at one end and the other end of the substrate 14. The USB memory 11 further includes the branch circuit 23 which electrically discriminates the memory 26 of the USB memory 11 from another USB memory or the like connected to the USB back I/F 22 which is electrically connected to the female USB terminal 13.

When the male USB terminal 12-2 of the USB memory 11-2 is inserted into the female USB terminal 13-1 of the USB memory 11-1, the female USB terminal 13-1 can be electrically connected to the male USB terminal 12-2, and the USB memories 11-1 and 11-2 can be electrically connected to each other.

Hence, even when the memory capacity is to be increased upon connecting the USB memory to the host apparatus or the like which has only one USB terminal, the memory 26-2 of the connected USB memory 11-2 can be used. Accordingly, the number of terminals of the host need not be increased, and a hub or the like need not be additionally prepared for connecting memories.

Also, when connecting the three or more USB memories 11-1 to 11-4, . . . , these USB memories can be connected in series in a staggered pattern (FIG. 8).

On the other hand, when connecting a plurality of USB memories each having female USB terminals arranged along one end of a substrate on its surface opposite to the surface on which male USB terminals are arranged, the USB memories are connected in a step-like shape (FIG. 10). With this structure, the occupied space becomes large and the appearance of the USB memory becomes poor, so buying appetite may suffer.

As described above, in the semiconductor memory device and connection method thereof according to this embodiment, in order to increase the memory capacity, the occupied area can be decreased without increasing the number of terminals and hubs, and the USB memories 11-1 to 11-4, . . . can be connected in series. This is advantageous in saving the space.

(2) Improvable for Convenience

The USB memory 11 includes the side indicator 17 which is arranged on the side surface of the housing 15 to indicate that the USB memory 11 is in operation. More specifically, the side indicator 17 is arranged on the surface of the housing 15 in correspondence with the side surface of the substrate 14.

On the other hand, when connecting a plurality of USB memories each having an indicator arranged on the lower (or upper) surface of the housing, it may not be possible to confirm the operations of these USB memories (FIG. 10). This problem occurs depending on the position of the USB terminal of the host apparatus.

However, the side indicator 17 according to this embodiment is arranged on the side surface of the housing 15. Hence, even when the USB memory 11 operates in cooperation with other USB memories, such disadvantage can be solved. As a result, the operation states of all the USB memories 11-1 to 11-4, . . . can be confirmed, thus improving convenience.

### Second Embodiment (Example with Wireless Function)

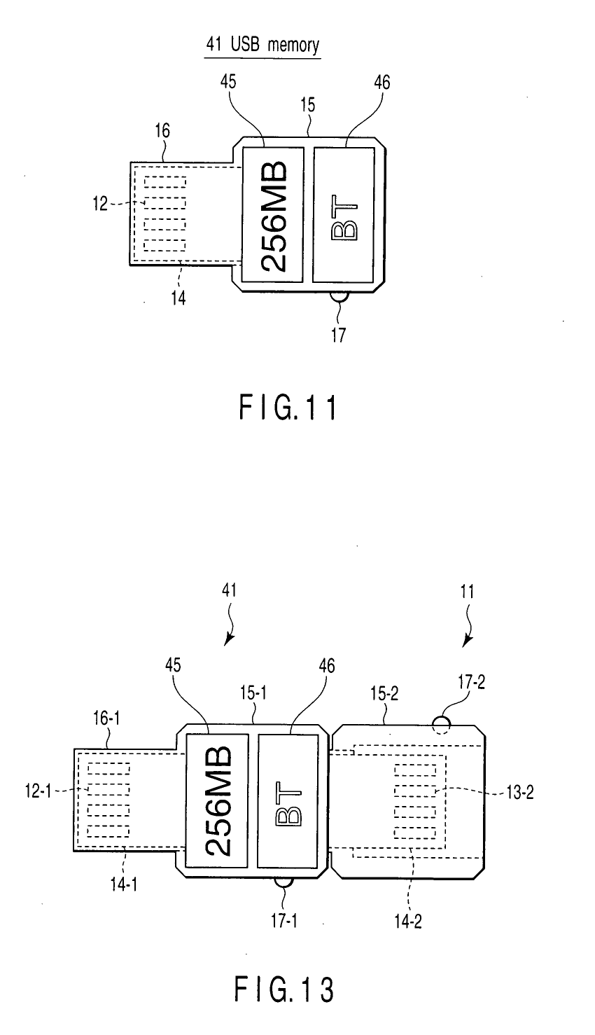

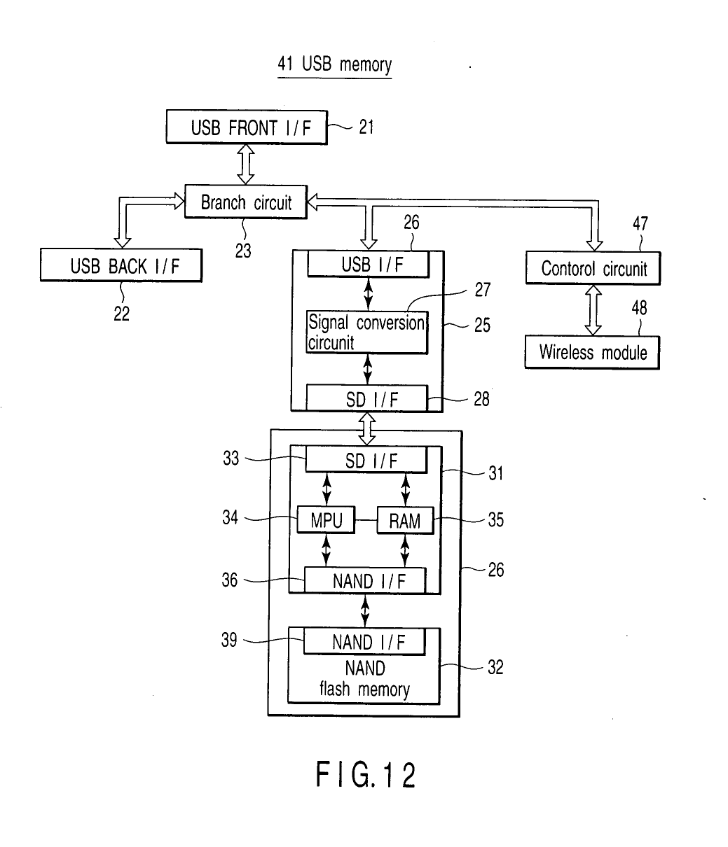

A semiconductor memory device according to the second embodiment of the present invention will be described next with reference to FIGS. 11 and 12. This embodiment relates to an example of a semiconductor memory device having a wireless function. The description which is the same as that in the first embodiment will not be repeated. FIG. 11 is a plan view showing the semiconductor memory device according to this embodiment. FIG. 12 is a block diagram showing the semiconductor memory device according to this embodiment.

As shown in FIGS. 11 and 12, a USB memory 41 according to this embodiment is different from the USB memory 11 according to the first embodiment in that the USB memory 41 includes a capacity identification unit 45 and wireless identification unit 46 on the surface of a housing 15.

The capacity identification unit 45 displays the capacity of a memory 26 of the USB memory 41. For example, in this embodiment, the memory capacity identification unit 45 displays a memory capacity of 256 MB with letters.

The wireless identification unit 46 displays the wireless function and format of the USB memory 41. For example, in this embodiment, the wireless identification unit 46 displays, with letters, that the USB memory 41 has a Bluetooth® wireless function (to be referred to as a BT hereinafter).

Furthermore, the USB memory 41 according to this embodiment is different from the USB memory 11 according to the first embodiment in that the USB memory 41 includes a control circuit 47 and a wireless module 48.

The wireless module 48 wirelessly transmits/receives data and the like to/from an external device.

The control circuit 47 records, in the memory 26, data and the like transmitted from the external device to the wireless module 48, and controls the wireless module 48 to transmit data and the like from the memory 26 to the external device.

<Connection Operation of USB Memories (Connection Operation of Two USB Memories)>

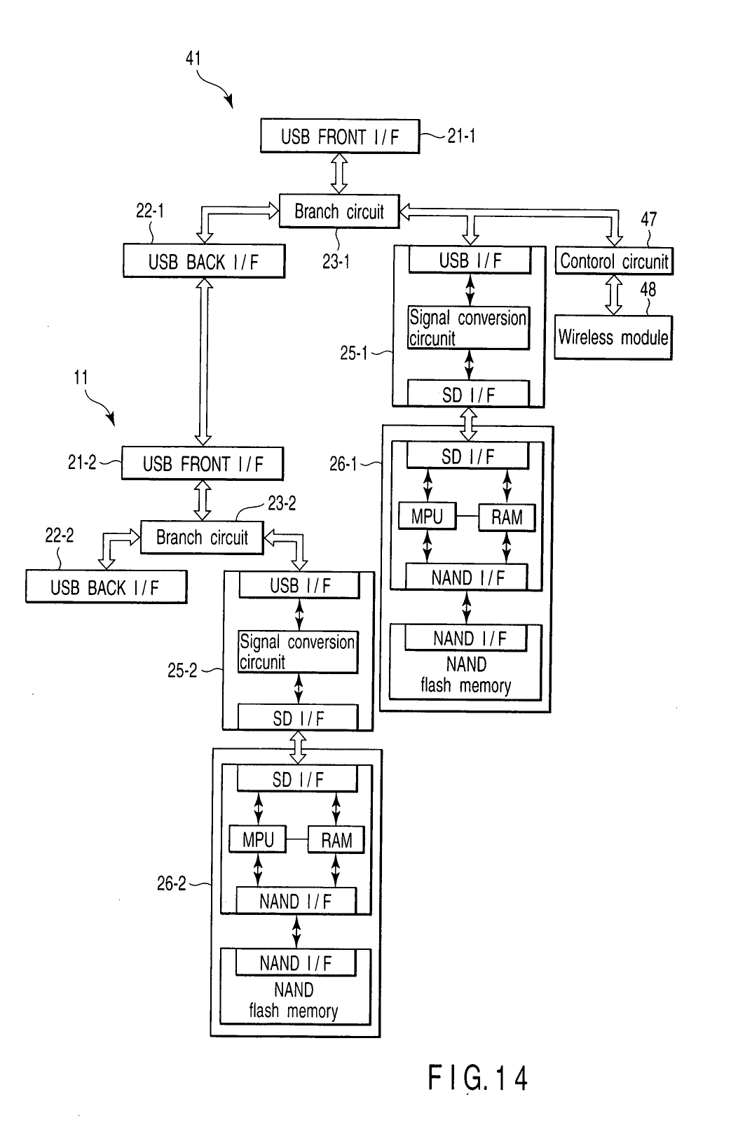

The connection operation of the USB memories according to this embodiment will be described below with reference to FIGS. 13 and 14. FIG. 13 is a view for explaining the connection operation of the USB memories 41 and 11 according to this embodiment. FIG. 14 is a block diagram when connecting the USB memories according to this embodiment. In this description, assume that the USB memory 41 according to this embodiment and the USB memory 11 according to the first embodiment are connected.

As shown in FIGS. 13 and 14, a male USB terminal 12-2 of the USB memory 11 is inserted into a female USB terminal 13-1 of the USB memory 41 to connect the USB memories 41 and 11 to each other.

In this case, the spring 19 presses both substrates 14-1 and 14-2 by its elasticity, and the female and male USB terminals 13-1 and 12-2 are connected by pressure to be electrically connected.

With this operation, the USB memories 41 and 11 are connected via a USB back I/F 22-1 and a USB front I/F 21-2 to drive both memories 26-1 and 26-2, the control circuit 47, and the wireless module 48 using branch circuits 23-1 and 23-2. Additionally, in this case, side indicators 17-1 and 17-2 continuously emit light to indicate that the USB memories 41 and 11 are in operation.

The semiconductor memory device and connection method thereof according to this embodiment have the above-described effects (1) and (2).

The semiconductor memory device according to this embodiment further includes the control circuit 47 and the wireless module 48. The control circuit 47 records, in the memory 26, data and the like transmitted from an external device to the wireless module 48, and controls the wireless module 48 to transmit data and the like from the memory 26 to the external device. With this operation, the memory 26 can store audio data and the like received from the external device, thus improving convenience.

Furthermore, since the USB memory 41 can be connected to the USB memory 11 according to this embodiment, the memory 26-2 of the USB memory 11 can also be used. This is advantageous in increasing the capacity.

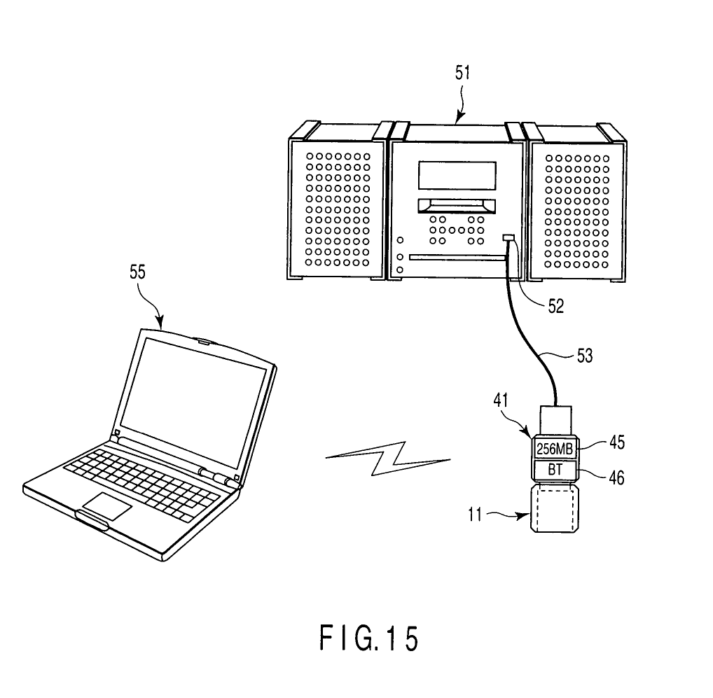

As shown in FIG. 15, assume that the present invention may be applied to a case wherein the USB memory 11 is connected to the USB memory 41 which is connected to a USB terminal 52 of a home component stereo 51 via a wire 53. In this case, while the USB memories 41 and 11 are connected to the home component stereo 51, a user can purchase music data and the like available on the Internet by using a notebook PC 55.

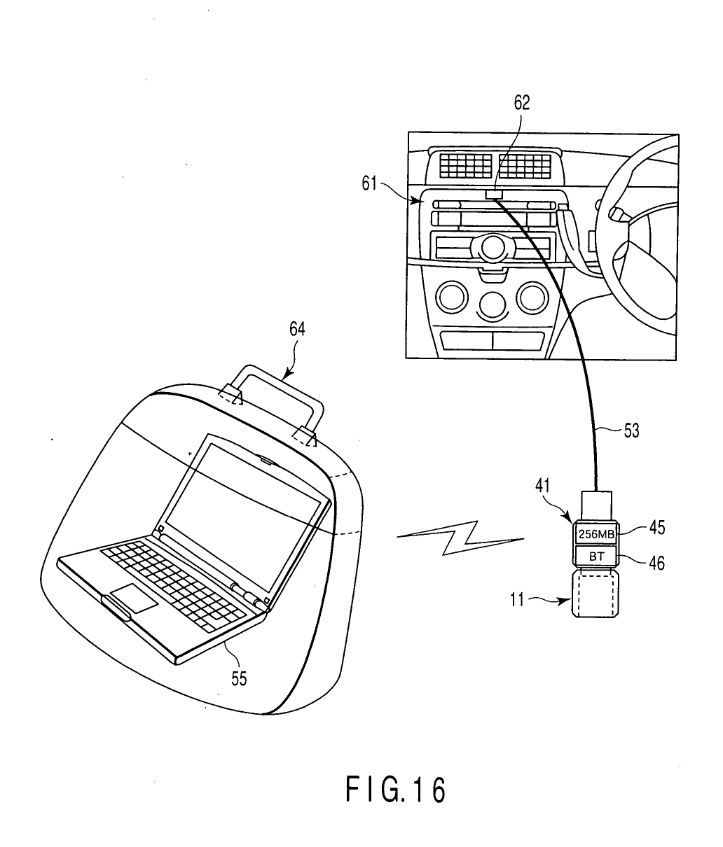

Also, as shown in FIG. 16, assume that the present invention may be applied to a case wherein the USB memory 11 is connected to the USB memory 41 which is connected to a USB terminal 62 of a car stereo 61 via the wire 53. In this case, while the USB memories 41 and 11 are connected to the car stereo 61, the user can purchase music data and the like available on the Internet by using the notebook PC 55 in a bag 64 placed on a passenger seat. The memories 26-1 and 26-2 of the USB memories 41 and 11 can save music data, image data, and the like, and play back these data in a car without the notebook PC 55.

As described above, the scope of application of the USB memories 41 and 11 can be widened by applying such arrangement as needed, and this is advantageous in improving convenience.

[Modifications (Other Examples of Identification Unit)]

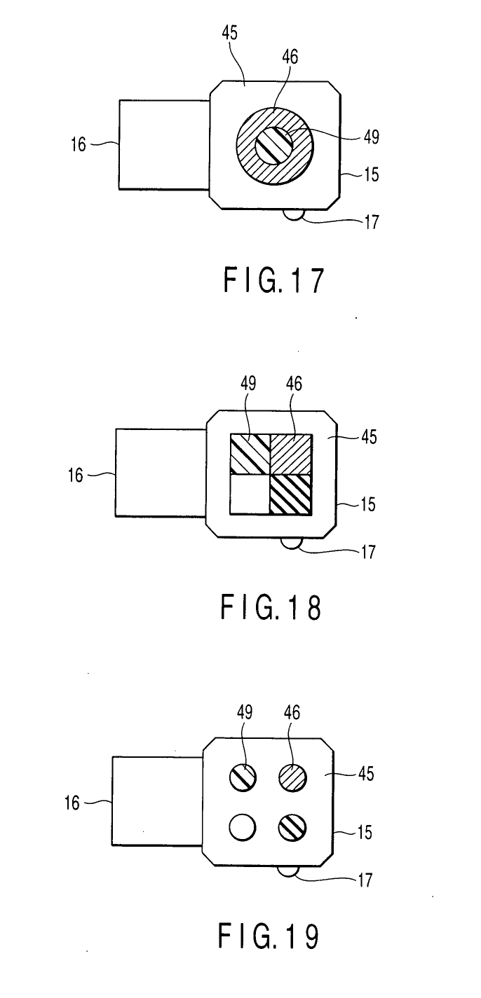

The modifications of the semiconductor memory device according to the second embodiment will be described next with reference to FIGS. 17 to 22. These modifications relate to examples of the identification unit. The description which is the same as that in the first embodiment will not be repeated.

The USB memory shown in FIG. 17 is different from the USB memory 41 according to the second embodiment in that the capacity identification unit 45 is identified as a non-hatched portion on the housing 15, the wireless identification unit 46 is identified as the peripheral portion of a central circle on the housing 15, and a USB-SD identification unit 49 is further included. The USB-SD identification unit 49 identifies that the memory 26 is an integrated SD™ memory card.

The USB memory shown in FIG. 18 is different from the USB memory 41 according to the second embodiment in that the wireless identification unit 46 and the USB-SD identification unit 49 are identified as square shapes on the housing 15.

The USB memory shown in FIG. 19 is different from the USB memory 41 according to the second embodiment in that the wireless identification unit 46 and the USB-SD identification unit 49 are identified as circular shapes on the housing 15.

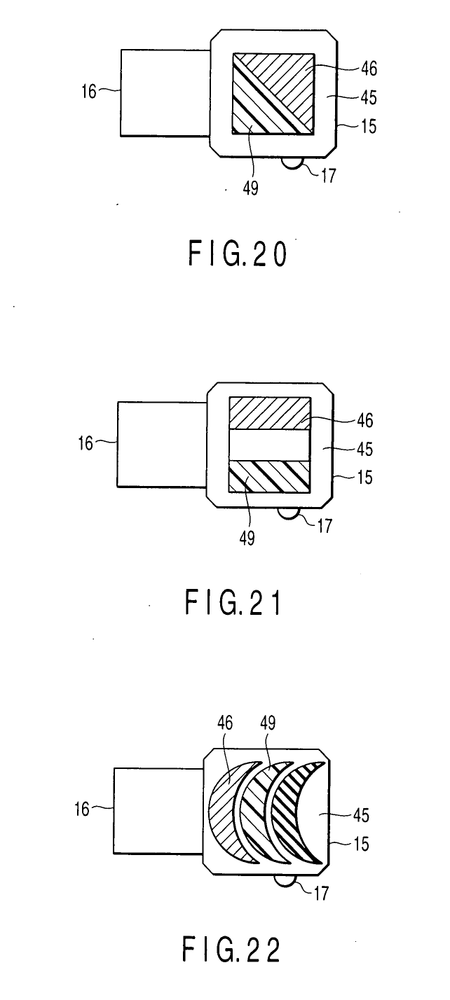

The USB memory shown in FIG. 20 is different from the USB memory 41 according to the second embodiment in that the wireless identification unit 46 and the USB-SD identification unit 49 are identified as triangle shapes on the housing 15.

The USB memory shown in FIG. 21 is different from the USB memory 41 according to the second embodiment in that the wireless identification unit 46 and the USB-SD identification unit 49 are identified as rectangular shapes on the housing 15.

The USB memory shown in FIG. 22 is different from the USB memory 41 according to the second embodiment in that the wireless identification unit 46 and the USB-SD identification unit 49 are identified as semilunar shapes on the housing 15.

The semiconductor memory device and connection method thereof according to this embodiment have the above-described effects (1) and (2).

According to these modifications, the shape of the identification unit can be variously changed, as needed, in correspondence with the function such as the wireless function installed in the USB memory.

Note that the identification unit can be identified not only by hatching but also by coloring in correspondence with various functions. For example, the memory identification unit can be white, the USB-SD identification unit can be blue, the wireless identification unit can be blue, and the wireless USB-SD identification unit can be blue and yellow.

### Third Embodiment (Example of Bus Format)

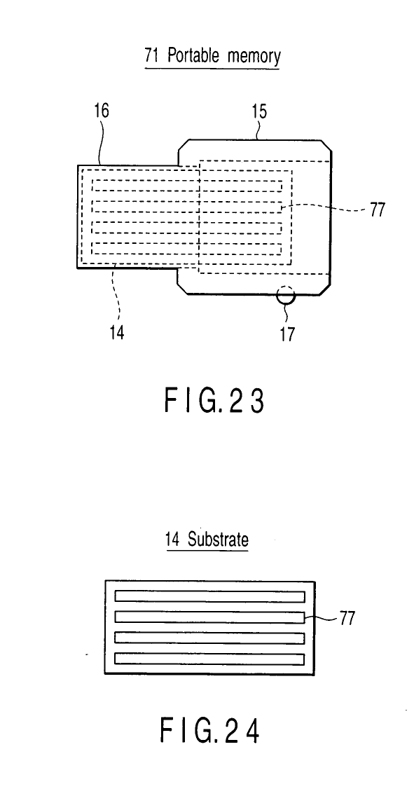

A semiconductor memory device according to the third embodiment will be described next with reference to FIGS. 23 to 26. The semiconductor memory device according to this embodiment relates to an example applied to a bus format. The description which is the same as that in the first or second embodiment will not be repeated.

As shown in FIGS. 23 to 26, a portable memory 71 according to this embodiment is different from that according to the first or second embodiment in that a bus (a transmission/reception unit) 77 is formed from one end to the other end on the surface of a substrate 14.

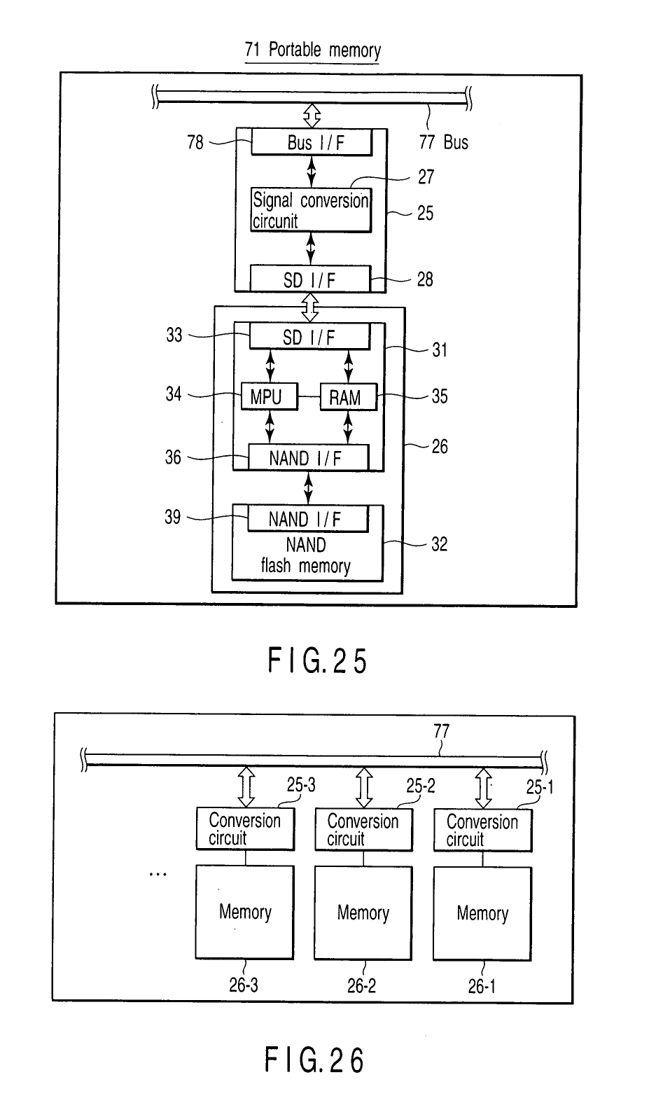

As shown in FIG. 25, a conversion circuit 25 is different from that in the first or second embodiment in that a bus interface (bus I/F) 78 is included. With this arrangement, the conversion circuit 25 converts, into a predetermined data or the like, data and the like transmitted/received between the bus 77 and a memory 26. In this embodiment, the conversion circuit 25 converts a signal defined in a bus format into a signal defined based on an SD™ memory card, and, in return, coverts a signal defined based on the SD™ memory card into a signal defined in the bus format.

<Connection Operation of Memories 71>

The connection operation of memories 71 according to this embodiment will be described next with reference to FIG. 26. FIG. 26 is a block diagram when connecting the memories according to the third embodiment. In this case, assume that a plurality of memories 71 each having the same arrangement as that of the above-described portable memory 71 are connected.

Similar to the first and second embodiments, the male terminal of one memory 71 is inserted into the female terminal of another portable memory 71, and these memories 71 are connected.

In this case, a spring 19 presses both substrates 14 by its elasticity, and the female and male terminals are connected by pressure, and electrically connected to the bus 77.

Accordingly, the semiconductor memory device according to this embodiment is different from that in the hub format according to the first and second embodiments in that the bus I/Fs in conversion circuits 25-1 to 25-3, . . . are directly connected to the bus 77, and the memories are electrically connected to each other in parallel. In this state, side indicators 17 continuously emit light or the like to indicate that the memories 71 are in operation.

The semiconductor memory device and connection method thereof according to this embodiment have the above-described effects (1) and (2).

Furthermore, the memory 71 according to this embodiment includes the bus I/F 78 and bus 77 on the surface of the substrate 14. This arrangement in which the memories are electrically connected in parallel can be applied as needed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a substrate;
a memory electrically connected to the substrate;
a first and a second transmission/reception units transmitting a signal supplied by the memory and receiving a signal to be supplied to the memory, both arranged on a surface of the substrate;
a branch circuit which is electrically connected to the first and the second transmission/reception units, and electrically discriminates the second transmission/reception unit from the memory; and
a conversion circuit which converts the signal between the branch circuit and the memory into a signal in a predetermined format.

2. The device according to claim 1, further comprising:
a housing arranged to cover the substrate; and
an indicator arranged on a surface of the housing in correspondence with a side surface of the substrate.

3. The device according to claim 1, wherein
the first transmission/reception unit is arranged at one end of the substrate, and
the second transmission/reception unit is arranged at the other end opposite to the first transmission/reception unit on the substrate.

4. The device according to claim 1, wherein the conversion circuit includes a signal conversion circuit which converts a format of a signal, a first interface inserted between the branch circuit and the signal conversion circuit, and a second interface inserted between the signal conversion circuit and the memory.

5. The device according to claim 1, wherein the memory includes a nonvolatile memory, and a controller which controls the nonvolatile memory.

6. The device according to claim 1, further comprising:
a wireless module which is mounted on the substrate, and configured to wirelessly transmit/receive an external signal; and
a control circuit which is mounted on the substrate, electrically connected to the branch circuit, and configured to control transmission/reception of a signal to/from the wireless module.

7. The device according to claim 6, further comprising:
a capacity identification unit arranged on the housing to display a capacity of the memory; and
a wireless identification unit arranged on the housing to display a wireless function of the wireless module.

8. The device according to claim 1, wherein
the first transmission/reception unit is a male USB terminal, and
the second transmission/reception unit is a female USB terminal.

9. A semiconductor memory device comprising:
a substrate;
a memory electrically connected to the substrate;
a transmission/reception unit having a bus format, transmitting a signal supplied by the memory and receiving a signal to be supplied to the memory, and formed from one end to the other end on a surface of the substrate; and
a conversion circuit which is electrically connected to the substrate, and converts the signal between the transmission/reception unit and the memory into a signal in a predetermined format.

10. The device according to claim 9, further comprising:
a housing arranged to cover the substrate; and
an indicator arranged on a surface of the housing in correspondence with a side surface of the substrate.

11. The device according to claim 9, wherein the conversion circuit includes a signal conversion circuit which converts a format of a signal, a first interface inserted between the branch circuit and the signal conversion circuit, and a second interface inserted between the signal conversion circuit and the memory.

12. The device according to claim 9, wherein the memory includes a nonvolatile memory, and a controller which controls the nonvolatile memory.

13. A connection method of a semiconductor memory device which includes a substrate, a memory mounted on the substrate, a first and a second transmission/reception units transmitting a signal supplied by the memory and receiving a signal to be supplied to the memory, both arranged on a surface of the substrate, a branch circuit which is electrically connected to the first and the second transmission/reception units, and electrically discriminates the second transmission/reception unit from the memory, and a conversion circuit which converts the signal between the branch circuit and the memory into a signal in a predetermined format, the method comprising:
electrically connecting the first transmission/reception unit and the second transmission/reception unit via the branch circuit, and connecting the plurality of semiconductor memory devices in a staggered pattern.

14. The method according to claim 13, wherein the semiconductor memory device further comprises:
a housing arranged to cover the substrate; and
an indicator arranged on a surface of the housing in correspondence with a side surface of the substrate.

15. The method according to claim 13, wherein
the first transmission/reception unit is arranged at one end of the substrate, and
the second transmission/reception unit is arranged at the other end opposite to the first transmission/reception unit on the substrate.

16. The method according to claim 13, wherein the conversion circuit includes a signal conversion circuit which converts a format of a signal, a first interface inserted between the branch circuit and the signal conversion circuit, and a second interface inserted between the signal conversion circuit and the memory.

17. The method according to claim 13, wherein the memory includes a nonvolatile memory, and a controller which controls the nonvolatile memory.

18. The method according to claim 13, wherein the semiconductor memory device further comprises:
a wireless module which is mounted on the substrate and configured to wirelessly transmit/receive an external signal; and
a control circuit which is mounted on the substrate, electrically connected to the branch circuit, and configured to control transmission/reception of a signal to/from the wireless module.

19. The method according to claim 18, wherein the semiconductor memory device further comprises:
a capacity identification unit arranged on the housing to display a capacity of the memory; and
a wireless identification unit arranged on the housing to display a wireless function of the wireless module.

20. The method according to claim 13, wherein
the first transmission/reception unit is a male USB terminal, and
the second transmission/reception unit is a female USB terminal.
